(19) United States
(12) Patent Application Publication
(10) Pub. No.: US 2007/0020792 A1
(43) Pub. Date: Jan. 25, 2007

(54) OPTICAL SHEET, BACKLIGHT UNIT, ELECTRO-OPTIC DEVICE, ELECTRONIC DEVICE, METHOD FOR MANUFACTURING OPTICAL SHEET, AND METHOD FOR CUTTING OPTICAL SHEET

(75) Inventor: Hironori HASEI, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Shinjuku-ku, Tokyo (JP)

(21) Appl. No.: 11/425,200

(22) Filed: Jun. 20, 2006

(30) Foreign Application Priority Data
Jul. 25, 2005 (JP) 2005-213801

(51) Int. Cl. H01L 21/00

(52) U.S. Cl. 438/30

(57) ABSTRACT

A method for manufacturing an optical sheet includes: a) discharging a liquid lens material onto a sheet having a light-transmitting property, the liquid lens material being to be a material of micro lenses; b) discharging a liquid material onto the sheet, the liquid material being to be a material of recognition marks; and c) hardening the lens material and the liquid material to form the micro lenses and the recognition marks.

### BACKGROUND

1. Technical Field

The present invention relates to an optical sheet, a backlight unit, an electro-optic device, an electronic device, a method for manufacturing an optical sheet, and a method for cutting an optical sheet.

2. Related Art

There are known methods for obtaining optical sheets of desired cutting sizes by cutting a large-size optical sheet having micro lenses formed thereon by using scissors, a cutter, a laser, or the like (see, for example, JP-A-2004-155101).

JP-A-2004-155101 is an example of related art.

In conventional methods, however, before a large-size optical sheet is actually cut into individual sheets of desired cutting sizes, it is necessary to subject the large-size optical sheet to measurement to determine cutting positions for each individual sheet so that the individual sheets will have the desired sizes. Therefore, it takes a long time to determine the cutting positions. Moreover, if sheets of different cutting sizes are to be obtained from one large-size sheet, erroneous measurement tends to happen when determining the cutting positions for each sheet.

### SUMMARY

An advantage of the invention is to provide an optical sheet, a backlight unit, an electro-optic device, an electronic device, a method for manufacturing an optical sheet, and a method for cutting an optical sheet, in which cutting positions can easily be determined accurately to obtain sheets of desired cutting sizes.

According to one aspect of the invention, a method for manufacturing an optical sheet includes a) discharging a liquid lens material onto a sheet having a light-transmitting property, the liquid lens material being to be a material of micro lenses; b) discharging a liquid material onto the sheet, the liquid material being to be a material of recognition marks; and c) hardening the lens material and the liquid material to form the micro lenses and the recognition marks.

Thus, in step (a), the lens material that is to be the material of the micro lenses is applied onto the sheet in the form of droplets. In step (b), the liquid material that is to be the material of the recognition marks is applied onto the sheet in the form of droplets. Then, in step (c), the lens material and the liquid material are hardened to form the micro lenses and the recognition marks. The micro lenses are used to condense or diffuse light. The recognition marks are used for determination of cutting positions when cutting the sheet having the micro lenses formed thereon to obtain a sheet of a desired size. Accordingly, it is easy to determine cutting positions for a cutting size accurately because the cutting size is defined by the positions of the recognition marks.

It is preferable that step (a) and step (b) be performed simultaneously.

Thus, the discharging of the liquid material for the micro lenses and the discharging of the liquid material for the recognition marks are performed in the same step. This serves to shorten a processing time.

It is preferable that, in step (b), the liquid material be discharged such that the liquid material dropped on the sheet will assume a form different from a shape of the micro lenses.

Thus, the shape of the recognition marks formed by hardening the liquid material discharged for the recognition marks is different from the shape of the micro lenses. This makes it possible to easily distinguish between the recognition marks and the micro lenses, which makes it easier to recognize the cutting positions.

It is preferable that, in step (b), the liquid material be discharged such that the recognition marks will have a different size from that of the micro lenses.

Thus, the size of the recognition marks formed by hardening the liquid material discharged for the recognition marks is different from the size of the micro lenses. This makes it possible to easily distinguish between the recognition marks and the micro lenses, which makes it easier to recognize the cutting positions.

It is preferable that, in step (b), the liquid material discharged be a material that allows the recognition marks to have a different color from that of the micro lenses.

Thus, the color of the recognition marks formed by hardening the liquid material discharged for the recognition marks is different from the color of the micro lenses. This makes it possible to easily distinguish between the recognition marks and the micro lenses, which makes it easier to recognize the cutting positions.

It is preferable that the liquid material for the recognition marks be identical to the liquid lens material for the micro lenses.

Thus, the material of the recognition marks is identical to the material of the micro lenses. Therefore, material control can be easily performed.

It is preferable that, in step (b), the liquid material be discharged such that an interval between each of the recognition marks and any of the micro lenses will be greater than an interval between the micro lenses.

Thus, the interval between each recognition mark and any micro lens is greater than the interval between the micro lenses. Accordingly, even if the same lens material is used for the recognition marks and the micro lenses, it is possible to easily distinguish between the recognition marks and the micro lenses, which makes it easier to recognize the cutting positions.

It is preferable that, in step (b), the liquid material be discharged onto opposing edge portions of the sheet.

Thus, the recognition marks are formed by hardening the liquid material discharged onto the opposing edge portions of the sheet, which portions will be an edge of a subdivision of the sheet to be obtained by cutting and where no diffusing lenses need be disposed. Therefore, a diffusion function is less affected.

It is preferable that, in step (b), the liquid material be discharged onto opposing edge portions of the sheet such that the resulting recognition marks will be disposed at a predetermined interval.

Thus, the recognition marks are formed at a predetermined interval by hardening the liquid material discharged onto the opposing edge portions of the sheet. Therefore, by selecting proper recognition marks and cutting the sheet based on the selected recognition marks, it is possible to easily obtain an optical sheet of a desired size by cutting.

It is preferable that the method for manufacturing an optical sheet further include: d) cutting the optical sheet based on the recognition marks after step (c).

Thus, a large-size optical sheet is cut based on the recognition marks corresponding with a desired cutting area. Therefore, it is possible to obtain a desired optical sheet accurately by cutting the large-size optical sheet.

According to another aspect of the invention, an optical sheet is manufactured by the above-described method.

Thus, it is possible to provide an optical sheet of an accurate cutting size.

According to yet another aspect of the invention, a method for cutting an optical sheet as described above based on the recognition marks includes: a) mounting the optical sheet on a table unit and fixing the optical sheet on the table unit; b) recognizing the recognition marks formed on the optical sheet at positions corresponding with a desired cutting size by using a recognition unit; and c) cutting the optical sheet based on the recognized recognition marks by using a cutting machine.

Thus, the recognition marks on the optical sheet fixed onto the table unit are recognized by using the recognition unit, and the optical sheet is cut based on the recognized recognition marks by using the cutting machine. Therefore, it is possible to easily obtain an optical sheet of a desired cutting size by cutting.

It is preferable that the table unit have a porous tabletop, and that in step (a), the optical sheet be fixed on the table unit by sucking the optical sheet through openings of the porous tabletop.

Thus, use of the porous tabletop prevents a sheet cut away from the large-size sheet from being displaced. Therefore, when further cutting the cut-away sheet, the cutting can be performed accurately based on the recognition marks disposed in edge portions of the initial large-size sheet.

It is preferable that, in step (b), the recognition unit recognize the recognition marks by obtaining an image of the recognition marks and performing image processing.

Thus, the recognition marks are recognized via image processing. Therefore, it is possible to obtain accurate cutting positions.

According to yet another aspect of the invention, an optical sheet is manufactured by the method as described above.

Thus, an optical sheet is cut away from a large-size optical sheet by cutting the large-size optical sheet based on the recognition marks. Therefore, it is possible to provide a desired optical sheet with little discrepancy in cutting size.

According to yet another aspect of the invention, an optical sheet includes: a sheet having a light-transmitting property; first micro lenses formed on the sheet; and second micro lenses formed on the sheet as recognition marks.

Thus, micro lenses used for condensing or diffusing light and micro lenses that serve as the recognition marks are formed on the sheet of the optical sheet. The recognition marks are used for recognition of a cutting area corresponding with a desired cutting size. The recognition marks are formed at arbitrary positions so as to correspond with the desired cutting size. Therefore, it is easy to determine the cutting positions for the cutting size accurately.

It as preferable that an interval between each of the second micro lenses and any of the first micro lenses be greater than an interval between the first micro lenses.

Thus, the interval between each second micro lens that serves as a recognition mark and any first micro lens is greater than the interval between the first micro lenses. Therefore, it is possible to recognize the recognition marks easily, which makes it easier to recognize the cutting positions.

According to yet another aspect of the invention, an optical sheet of a desired size is obtained by cutting the optical sheet as described above based on the recognition marks.

Thus, by cutting the large-size optical sheet based on the recognition marks, it is possible to provide an optical sheet cut away therefrom that has accurate measurements.

According to yet another aspect of the invention, a backlight unit includes a light source and an optical sheet that diffuses light emitted from the light source, wherein as the optical sheet, the optical sheet as described above is used.

Thus, it is possible to provide a backlight unit with a reduced material cost.

According to yet another aspect of the invention, an electro-optic device includes the backlight unit as described above.

Thus, it is possible to provide an electro-optic device with a reduced material cost.

According to yet another aspect of the invention, an electronic device is equipped with the electro-optic device as described above.

Thus, it is possible to provide an electronic device with a reduced material cost.

### BRIEF DESCRIPTION OF THE DRAWINGS

The invention will be described with reference to the accompanying drawings, wherein like numbers reference like elements.

FIGS. 1A and 1D illustrate a structure of an optical sheet according to one embodiment of the invention. FIG. IA is a plan view of a large-size optical sheet, and FIG. 1B is a plan view of a subdivision of the large-size optical sheet.

FIG. 2 is a cross-sectional view illustrating a structure of a backlight unit.

FIG. 3 is a cross-sectional view illustrating a structure of a liquid crystal display device as an electro-optic device.

FIG. 4 is a perspective view illustrating a structure of a portable terminal as an electronic device.

FIGS. 5A and 5B illustrate a structure of a discharge head. FIG. 5A is a perspective view, partly cut away, thereof, and FIG. 5B is a detailed cross-sectional view thereof.

FIGS. 6A to 6D are step diagrams illustrating a method for manufacturing an optical sheet. FIG. 6E to 6G are step diagrams illustrating a method for cutting the optical sheet.

FIG. 7 is a block diagram illustrating a structure of a cutting device.

FIG. 8 is a plan view illustrating a structure of an optical sheet according to one variant.

### DESCRIPTION OF EXEMPLARY EMBODIMENTS

Hereinafter, embodiments of the invention will be described with reference to the accompanying drawings.

Structure of Optical Sheet

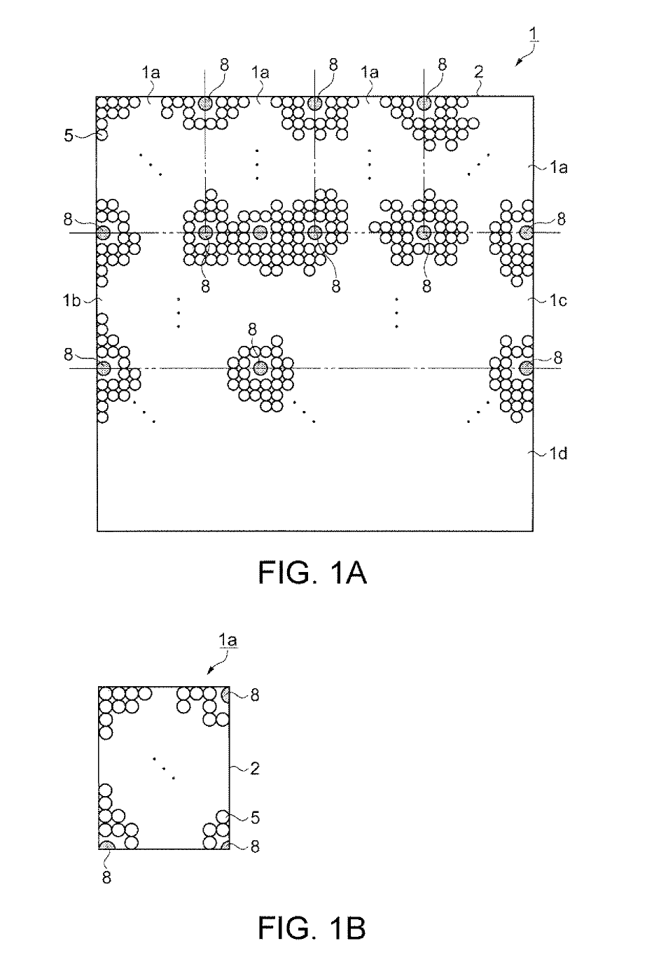

First, the structure of an optical sheet will now be described. FIG. 1A is a plan view of a large-size optical sheet, and FIG. 1B is a plan view of a subdivision of the large-size optical sheet obtained by cutting the large-size optical sheet so as to obtain a sheet of a desired cutting size.

In FIG. 1A, an optical sheet 1 includes a sheet 2 having a light-transmitting property and micro lenses 5 and recognition marks 8 formed on the sheet 2. The optical sheet 1 is a large-size optical sheet including optical sheets 1a, 1b, 1c, and 1d having different sizes.

The sheet 2 has a light-transmitting property. For example, a transparent resin material, such as acrylic resin, glass, quartz, polycarbonate, or polyester, is used for the sheet 2.

The micro lenses 5 are formed on the sheet 2 and have a substantially hemispherical shape. In addition, the micro lenses 5 are formed in substantially evenly-spaced arrangement.

The recognition marks 8 are marks for determining a cutting area to obtain an optical sheet of a desired size from the large-size optical sheet 1. The recognition marks 8 are formed in a peripheral region of the sheet 2 and have a substantially hemispherical shape. The recognition marks 8 are formed also on an inner region of the sheet 2 so as to correspond with diffusion sheets of desired sizes.

The recognition marks 8 are formed so as to have a larger diameter than that of the micro lenses 5. The interval between each of the recognition marks 8 and any of the micro lenses 5 is greater than the interval between the micro lenses 5. The recognition marks 8 are each formed of: an area that results from that greater interval where no micro lenses 5 are formed; and a projection having a hemispherical shape and placed substantially at the center of that area.

Cutting lines obtained by joining the recognition marks 8 with straight lines define rectangular areas. These rectangular areas correspond to the optical sheets 1a, 1b, 1c, and 1d of desired sizes. Cutting the large-size optical sheet 1 along the cutting lines that join the recognition marks results in, for example, the optical sheet 1a as illustrated in FIG. 1B.

The same material is used for the recognition marks 8 and the micro lenses 5. For example, ultraviolet curable acrylic resin or ultraviolet curable epoxy resin is used for the micro lenses 5 and the recognition marks 8. As an exemplary precursor, a polyimide precursor may be cited.

The ultraviolet curable resin contains a photopolymerization initiator and at least one of a prepolymer, an oligomer, and a monomer.

In the case of the ultraviolet curable acrylic resin, exemplary prepolymers or oligomers that can be used include: acrylates such as epoxy acrylate, urethane acrylate, polyester acrylate, polyether acrylate, and spiroacetal acrylate; and methacrylates such as epoxy methacrylate, urethane methacrylate, polyester methacrylate, and polyether methacrylate.

Exemplary monomers include: monofunctional monomers such as 2-ethylhexyl acrylate, 2-ethylhexyl methacrylate, 2-hydroxyethyl acrylate, 2-hydroxyethyl methacrylate, n-vinyl-2-pyrrolidone, Carbitol acrylate, tetrahydrofurfuryl acrylate, isobornyl acrylate, dicyclopentenyl acrylate, and 1,3-butanediol acrylate; bifunctional monomers such as 1,6-hexanediol diacrylate, 1,6-hexanediol methacrylate, neopentyl glycol acrylate, polyethylene glycol diacrylate, and pentaerythritol diacrylate; and multifunctional monomers such as trimethylolpropane triacrylate, trimethylolpropane trimethacrylate, pentaerythritol triacrylate, and dipentaerythritol hexacrylate.

Exemplary photopolymerization initiators include: acetophenone such as 2,2-dimethoxy-2-phenyl acetophenone; butyl phenone such as α-hydroxy isobutyl phenone and p-isopropyl-α-hydroxy isobutyl phenone; halogenated acetophenone such as p-tert-butyl dichloro acetophenone and α,α-dichlor-4-phenoxy acetophenone; benzophenone such as benzophenone, and n,n-tetraethyl-4,4-diamino benzophenone; benzyl such as benzyl, and benzyldimethyl ketal; benzoin such as benzoin and benzoinalkylether; oxime such as 1-phenyl-1,2-propanedione-2-(o-ethoxycarbonyl)oxime; xanthone such as 2-methylthio xanthone, and 2-chlorothio xanthone; benzoin ether such as benzoin ether and isobutyl benzoin ether; and radical forming compounds such as Michler's ketone. A resin obtained by curing the ultraviolet curable acrylic resin has an advantage of high transparency.

Exemplary polyimide precursors include polyamic acid, and polyamic acid long-chain alkyl ester. A polyimide resin obtained by subjecting the polyimide precursor to thermosetting has a transmittance of 80% or higher in the visible light range, and a high refractive index, i.e., that of 1.7 to 1.9. Thus, excellent lens effect is achieved.

Structure of Backlight Unit

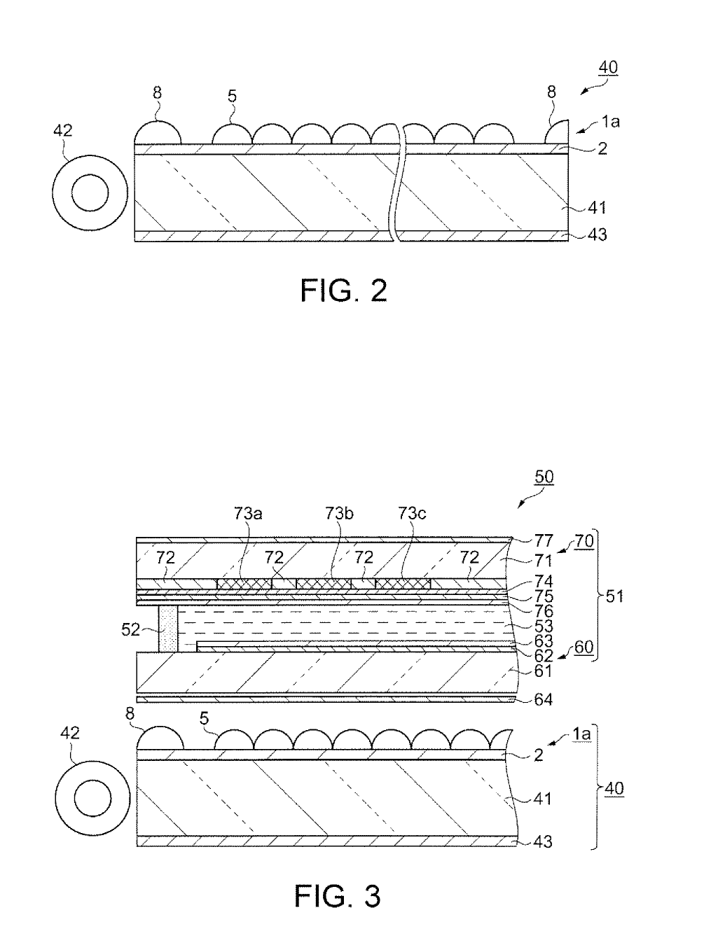

Next, a structure of a backlight unit will now be described. FIG. 2 is a cross-sectional view illustrating the structure of the backlight unit.

In FIG. 2, a backlight unit 40 includes: a light source 42; a light guide plate 41 disposed in the immediate vicinity of the light source 42; a reflector plate 43 disposed so as to face the light guide plate 41; and the optical sheet 1a disposed on a surface of the light guide plate 41 opposite to another surface thereof on which the reflector plate 43 is disposed. The light source 42 is a lighting device. Examples of the light source 42 include a cold cathode fluorescent tube. Light emitted from the light source 42 is propagated through the entire surface of the light guide plate 41 and emitted to the optical sheet 1a. The light emitted is diffused through the micro lenses 5 on the optical sheet 1a.

The light guide plate 41 has reflector dots (not shown) formed therein. When traveling within the light guide plate 41 while undergoing total reflection, a light beam from the light source 42 hits against the reflector dots to change the direction of travel. Light components that have thus achieved an angle of reflection less than the angle of total reflection are emitted from the light guide plate 41. The disposition of the reflector dots is such that the reflector dots are progressively more densely packed toward the farther end of the light guide plate 41 from the light source 42, so that even light reflection can be achieved. The optical sheet 1a also has a function of causing the reflector dots of the light guide plate 41 to be less visible by diffusion. The reflector plate 43 reflects, toward the light guide plate 41, light that has been emitted from the light source 42 into the light guide plate 41 and escaped from the reflector dots, so that light-use efficiency is improved.

The light guide plate 41, whose surface is substantially flat, has a transparency that allows light to pass therethrough. For example, a transparent resin material, such as acrylic resin, glass, quartz, polycarbonate, or polyester, is used for the light guide plate 41.

Structure of Electro-optic Device

Next, a structure of an electro-optic device will now be described, FIG. 3 is a cross-sectional view illustrating a structure of a liquid crystal display device as an electro-optic device.

In FIG. 3, a liquid crystal display device 50 includes: the backlight unit 40 that emits light; and a liquid crystal display unit 51 that receives the light emitted from the backlight unit 40 and performs a display.

The liquid crystal display unit 51 includes a lower substrate portion 60 that is disposed in the vicinity of the optical sheet 1a of the backlight unit 40; and an upper substrate portion 70 that is disposed opposite to the lower substrate portion 60. The lower substrate portion 60 and the upper substrate portion 70 secures an interspace therebetween defined by a sealant 52. A liquid crystal material 53 is sealed in the interspace.

The lower substrate portion 60 includes: a lower transparent substrate 61; a display electrode 62 formed on an upper surface of the lower transparent substrate 61; and an alignment layer 63 formed on an upper surface of the display electrode 62. In addition, a polarizing plate 64 is disposed on an opposite surface of the lower transparent substrate 61 with respect to the display electrode 62.

The upper substrate portion 70 includes: an upper transparent substrate 71; a black matrix 72 formed on a surface of the upper transparent substrate 71, the surface facing in the direction of the lower transparent substrate 61; and color filters 73a (R), 73b (G), and 73c (B), which serve as color components, formed in regions obtained by partition of the black matrix 72. The upper substrate portion 70 further includes: a protective layer 74 formed on an upper surface of the black matrix 72 and the color filters 73a, 73b, and 73c; a common electrode 75 formed on an upper surface of the protective layer 74; and an alignment layer 76 formed on an upper surface of the common electrode 75. In addition, a polarizing plate 77 is disposed on an opposite surface of the upper transparent substrate 71 with respect to the color filters 73a, 73b, and 73c.

The lower substrate portion 60 and the upper substrate portion 70 are adhered to each other by the adhesive force of the sealant 52. The liquid crystal material 53 is sealed in the interspace between the two substrate portions 60 and 70, the interspace being defined by the height of the sealant 52.

Structure of Electronic Device

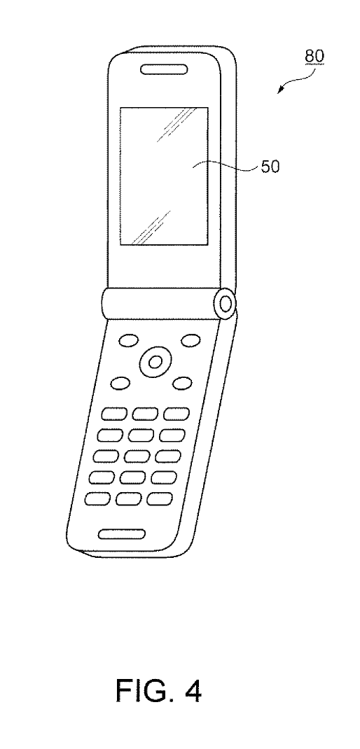

Next, a structure of an electronic device will now be described. FIG. 4 is a perspective view illustrating a structure of a portable terminal as an electronic device. In FIG. 4, a portable terminal 80 is equipped with the liquid crystal display device 50 as a display unit thereof.

Method for Manufacturing Optical Sheet

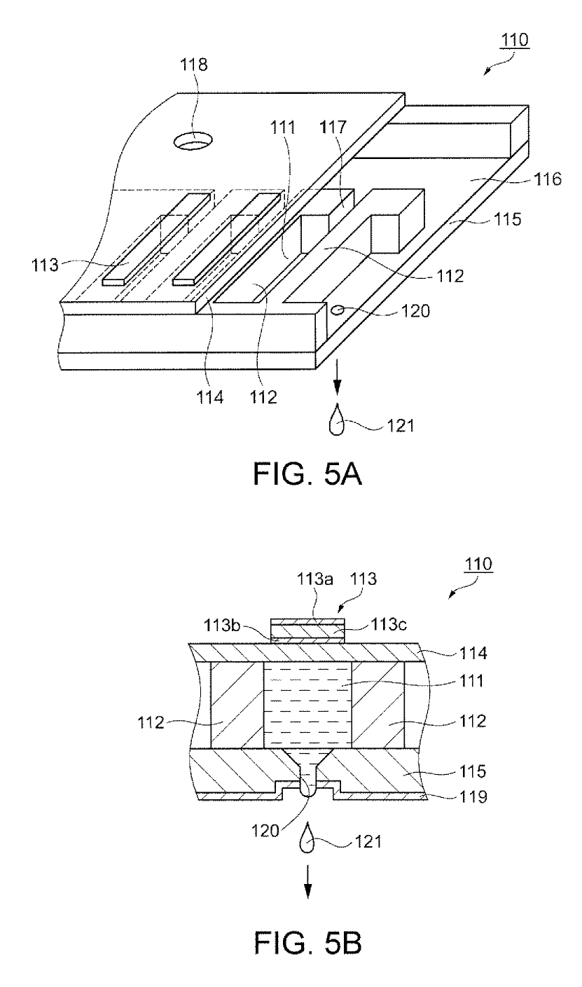

Next, a method for manufacturing an optical sheet will now be described. First, a discharge head used in this manufacturing method will be described. FIGS. 5A and 5B illustrate a structure of a discharge head. FIG. 5SA is a perspective view, partly cut away, thereof, and FIG. 5B is a detailed cross-sectional view thereof.

In FIG. 5A, a discharge head 110 includes a vibrating plate 114 and a nozzle plate 115. Between the vibrating plate 114 and the nozzle plate 115 is provided a liquid reservoir 116, which is always filled with a functional fluid supplied through a hole 118. Also, between the vibrating plate 114 and the nozzle plate 115 are positioned a plurality of banks 112. The vibrating plate 114, the nozzle plate 115, and a pair of banks 112 define a cavity 111 by surrounding it. A nozzle 120 is provided for each cavity 111. Accordingly, the number of cavities 11 is equal to that of nozzles 120. The liquid reservoir 116 supplies the functional fluid to the cavity 111 through a supply opening 11 7 positioned between the pair of banks 112.

As shown in FIG. 5B, a vibrator 113 is attached to the vibrating plate 114 so as to correspond to each cavity 111. The vibrator 113 includes a piezoelectric element 113c and a pair of electrodes 113a and 113b that sandwich the piezoelectric element 113c. Applying a drive voltage to the pair of electrodes 113a and 113b causes the functional fluid to be discharged through the corresponding nozzle 120 in the form of droplets 121. A functional fluid repellent layer 119, which is, for example, a Ni-tetrafluoroethylene eutectoid plated layer, is provided at the peripheral region of the nozzle 120 in order, for example, to prevent the flying droplets 121 from deviating and the nozzle 120 from clogging. Note that, instead of the vibrator 113, an electrothermal conversion element may be employed to discharge the functional fluid. In this case, discharging of a material fluid can be achieved by using thermal expansion of the material fluid caused by the electrothermal conversion element.

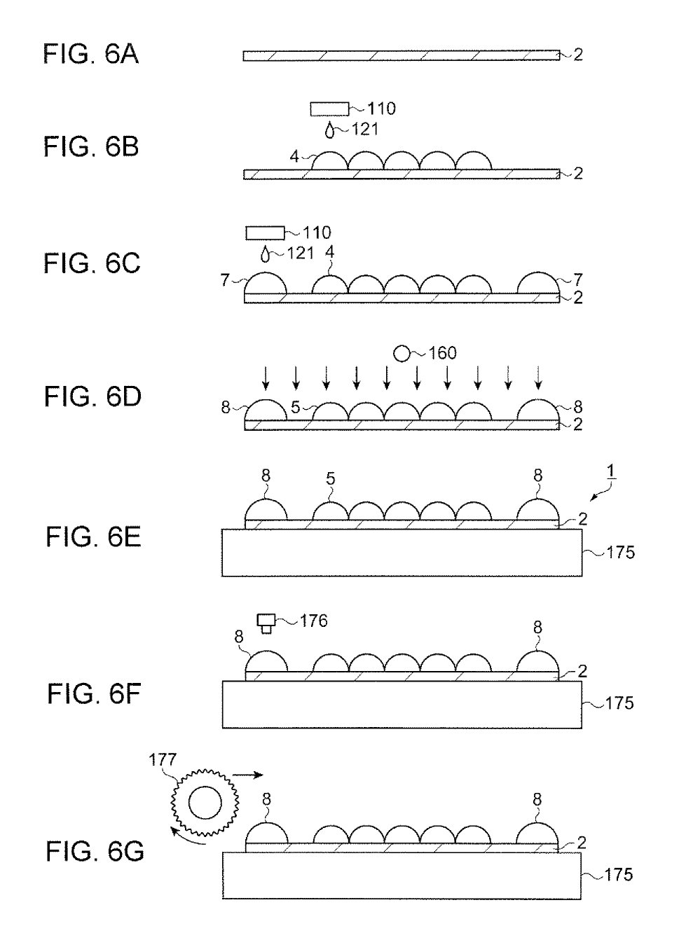

Next, the method for manufacturing the optical sheet will now be described. FIGS. 6A to 6D are step diagrams illustrating the method for manufacturing the optical sheet.

FIG. 6A illustrates a liquid-repellent treatment step. In this step, a surface of the sheet 2 is subjected to a liquid-repellent treatment. For the liquid-repellent treatment, a CF₄ plasma or the like is used,

FIG. 6B illustrates a first discharge step. In this step, the discharge head 110 discharges a liquid lens material 4 in the form of droplets 121 onto the sheet 2, so that the liquid lens material 4 is adhered to the sheet 2. The liquid lens material 4 is the material for the micro lenses. At the time of discharging, a control of the amount of the liquid lens material 4 to be discharged or other control is performed so that the liquid lens material 4 discharged will not have contact with any neighboring lens material 4.

FIG. 6C illustrates a second discharge step. In this step, the discharge head 110 discharges a liquid lens material 7 that is identical to the material of the micro lenses in the form of droplets 121 onto the sheet 2, so that the liquid lens material 7 is adhered to the sheet 2. The liquid lens material 7 is the material for the recognition marks. The lens material 7 is discharged onto positions corresponding with the size of desired optical sheets. At the time of discharging, it is so arranged that the interval between the lens material 7 discharged and any lens material 4 will be greater than the interval between the lens materials 4 so that the interval between the recognition mark 8 and any micro lens 5 will be greater than the interval between the micro lenses 5. Moreover, the amount of the lens material 7 discharged is controlled to be larger than that of the lens material 4 so that the resulting recognition mark 8 will have a larger diameter than that of the micro lenses 5.

FIG. 6D illustrates a hardening step. In this step, the lens materials 4 and 7 are hardened to form the micro lenses 5 and the recognition marks 8. For the hardening of the lens materials 4 and 7, an ultraviolet irradiation device 160 is used to irradiate the lens materials 4 and 7 with ultraviolet rays.

The large-size optical sheet 1 is manufactured through the above-described steps as illustrated by FIGS. 6A to 6D.

Method for Cutting Optical Sheet

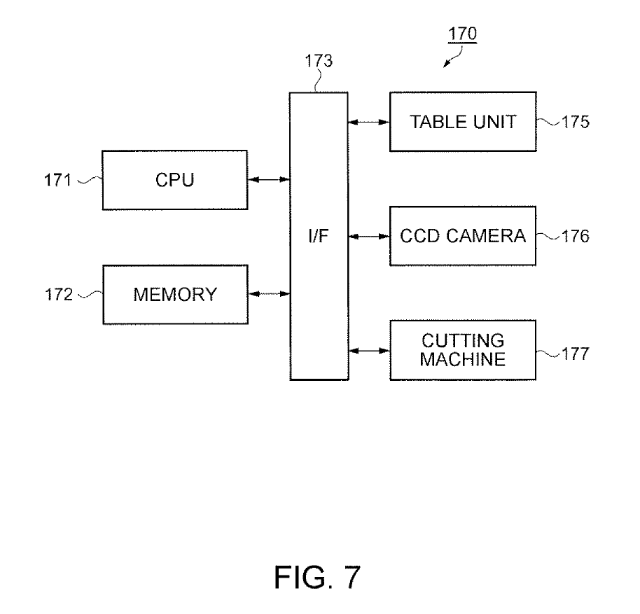

Next, a method for cutting the optical sheet 1 to obtain the optical sheet 1a of a desired size will now be described. First, a cutting device with which to cut the optical sheet 1 will be described. FIG. 7 is an electrical control block diagram for the cutting device.

In FIG. 7, a cutting device 170 includes: a CPU 171 that performs various computations as a processor; and a memory 172 for storing various information. A table unit 175, a CCD camera 176 as a recognition unit, and a cutting machine 177 are each connected to the CPU 171 and the memory 172 via an I/F (input/output interface) 173.

The memory 172 is a concept encompassing semiconductor memories such as RAM and ROM and external memory units such as a hard disk and a CD-ROM. In terms of functionality, the memory 172 has set therein: a memory area for storing a program software in which is described a control procedure for operation of the cutting device 170; an area for storing coordinate data for cutting the optical sheet 1; an area that functions, for example, as a work area of the CPU; and other memory areas of various types.

The CPU 171 performs a control for cutting predetermined positions of the optical sheet 1 in accordance with the program software stored within the memory 172. In terms of functionality, the CPU 171 has set therein, for example, a processing unit for driving the table unit 175, the CCD camera 176, and the cutting machine 177.

Next, the method for cutting the optical sheet will now be described with reference to FIGS. 6E to 6G.

FIG. 6E illustrates a suction step. In this step, the optical sheet 1 is mounted upon a mounting surface of the table unit 175 having a porous tabletop, and air is sucked in through openings of the porous tabletop. Thus, the optical sheet 1 is adhered to the table unit 175 by suction, so that the optical sheet 1 is fixed to the table unit 175.

FIG. 6F illustrates a recognition step. In this step, an image of the recognition marks 8 on the optical sheet 1 is taken by using the CCD camera 176, and the image is subjected to image processing to recognize the recognition marks that are to be cutting positions.

FIG. 6G illustrates a cutting step. In this step, the optical sheet 1 is cut along a virtual cutting line that joins the centers of two opposing recognition marks 8 on opposing sides. In cutting, the table unit 175 is moved in order to match the positions of the cutting machine 177 and the virtual cutting line, and the optical sheet 1 is cut by using the cutting machine 177.

The desired optical sheet 1a is obtained through the above-described steps as illustrated by FIGS. 6E to 6G.

Accordingly, the above-described embodiment has the following effects.

First, the formation of the recognition marks 8 eliminates the need to carry out a measurement, thereby making it easy to obtain the desired optical sheet 1a by cutting.

Second, the recognition marks 8 have a larger diameter than that of the micro lenses 5. This improves recognition performance and enables accurate recognition of cutting positions.

Third, the recognition marks 8 are each formed substantially at the center of an area where no micro lenses 5 are formed such that the interval between the recognition mark 8 and any micro lens 5 is greater than the interval between the micro lenses 5. This improves recognition performance and enables accurate recognition of cutting positions.

Fourth, the discharging of the lens material 7 in the second discharge step facilitates setting of the size of a desired sheet.

Note that the invention is not limited to the above-described embodiments, but variants as described below are also possible.

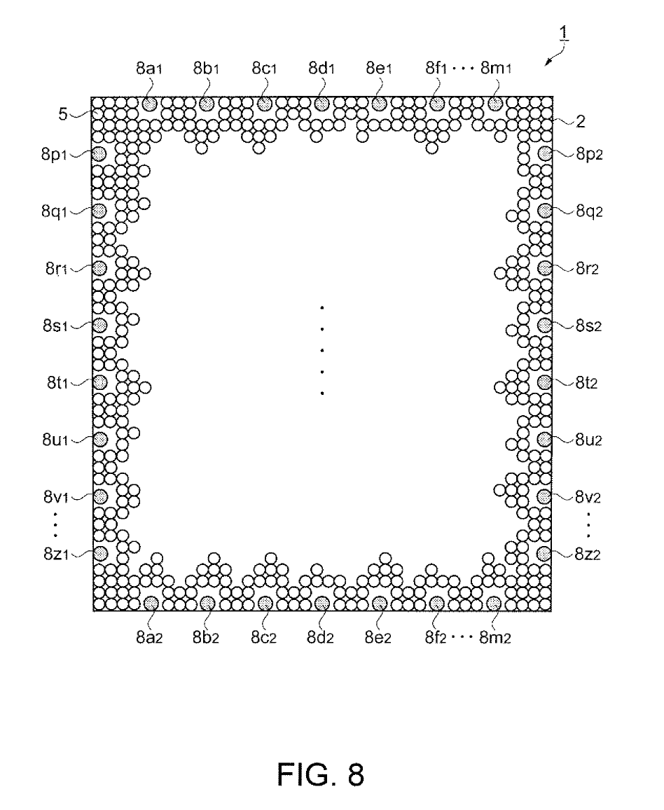

First, in the above-described embodiments, the recognition marks 8 are formed at positions corresponding with the sizes of the desired optical sheets 1a to Id. However, the invention is not limited to this. For example, as illustrated in FIG. 8, recognition marks 8a1 to 8m1, 8a2 to 8m2, 8p1 to 8z1, and 8p2 to 8z2 may be formed at a predetermined interval in a peripheral region of the sheet 2. This arrangement allows the recognition marks to function as scale marks. An optical sheet of an arbitrary size can be cut away and obtained by selecting proper recognition marks.

Second, in the above-described embodiments, the recognition marks 8 are formed in both the peripheral region and the inner region of the sheet 2. However, the invention is not limited to this. For example, the recognition marks 8 may be formed only in the peripheral region of the sheet 2. In this arrangement also, accurate cutting is possible because the optical sheet 1 is fixed by suction onto the porous tabletop of the table unit 175.

Third, in the above-described embodiments, the cutting lines pass through the recognition marks 8. However, the invention is not limited to this. For example, the cutting lines may not pass through any recognition mark. For example, with one particular recognition mark 8 recognized as a scale mark, cutting may be performed at a position of the nth micro lens 5 from that particular recognition mark 8. This further facilitates cutting away of an optical sheet of an arbitrary cutting size from the large-size optical sheet.

Fourth, in the above-described embodiments, the recognition marks 8 are formed so as to have a hemispherical shape, as with the micro lenses 5. However, the invention is not limited to this. The recognition marks 8 may be formed so as to have a different shape. For example, the recognition marks 8 may be formed so as to have a polygonal shape or an elliptical shape. This further improves the recognition performance of the recognition marks.

Fifth, in the above-described embodiments, the same liquid lens material as used for the micro lenses 5 is used for the recognition marks S. However, the invention is not limited to this. For example, a material having a different color may be used for the recognition marks 8. For example, for contrast with colorless, transparent micro lenses 5, the recognition marks 8 may be colored with white, black, yellow, red, blue, green, or the like. In this case, a pigment or a dye as a coloring matter is mixed with the liquid material. In addition, it is preferable that such a color be chosen as is easily recognizable when the recognition unit such as the CCD camera has taken an image of the recognition marks 8. This further improves the recognition performance of the recognition marks.

Sixth, in FIGS. 6B and 6C, the second discharge step is performed after the first discharge step. However, the invention is not limited to this. For example, the first discharge step and the second discharge step may be performed simultaneously. This serves to shorten the processing time. Moreover, in the case where the same lens material is used for both, it is possible to use the same discharge head to form the micro lenses 5 and the recognition marks 8.

Seventh, in FIG. 6E, the optical sheet 1 is fixed by suction onto the table unit 175 for cutting. However, the invention is not limited to this. For example, the optical sheet 1 may have a pressure-sensitive adhesive sheet attached on a surface thereof opposite to the surface on which the micro lenses 5 are formed, and be cut in a half-cutting manner. This eliminates the need to take into consideration positions of suction, which might be performed through the openings of the porous tabletop of the table unit. This further facilitates the setting of a plurality of sizes of optical sheets.

Eighth, in FIG. 6G, the cutting machine 177 is used for cutting the optical sheet 1. However, the invention is not limited to this. For example, a person may cut the optical sheet 1 using a cutter, etc. In this manner also, the formation of the recognition marks 8 makes it possible to omit a measuring operation and perform the cutting operation easily.

Ninth, in the above-described embodiments, the recognition marks 8 are formed so as to have a greater size than that of the micro lenses 5. However, the invention is not limited to this. The recognition marks 8 may be formed so as to have the same size as that of the micro lenses 5. In this arrangement also, providing an area where no micro lenses 5 are formed around each of the recognition marks 8 allows the recognition marks 8 to be recognizable. The areas where no micro lenses 5 are formed can be provided simply by subtracting, from discharge data (bitmap data), pieces of data representing the micro lenses 5 on those areas. Therefore, data setting for the recognition marks 8 can be easily performed.

What is claimed is:

1. A method for manufacturing an optical sheet, the method comprising:
a) discharging a liquid lens material onto a sheet having a light-transmitting property, the liquid lens material being to be a material of micro lenses;
b) discharging a liquid material onto the sheet, the liquid material being to be a material of recognition marks; and
c) hardening the lens material and the liquid material to form the micro lenses and the recognition marks.

2. The method for manufacturing an optical sheet according to claim 1, wherein
step (a) and step (b) are performed simultaneously.

3. The method for manufacturing an optical sheet according to claim 1, wherein
in step (b), the liquid material is discharged such that the liquid material dropped on the sheet will assume a form different from a shape of the micro lenses.

4. The method for manufacturing an optical sheet according to claim 1, wherein
in step (b), the liquid material is discharged such that the recognition marks will have a different size from that of the micro lenses.

5. The method for manufacturing an optical sheet according to claim 1, wherein
in step (b), the liquid material discharged is a material that allows the recognition marks to have a different color from that of the micro lenses.

6. The method for manufacturing an optical sheet according to claim 3, wherein
the liquid material for the recognition marks is identical to the liquid lens material for the micro lenses.

7. The method for manufacturing an optical sheet according to claim 6, wherein
in step (b), the liquid material is discharged such that an interval between each of the recognition marks and any of the micro lenses will be greater than an interval between the micro lenses.

8. The method for manufacturing an optical sheet according to claim 1, wherein
in step (b), the liquid material is discharged onto opposing edge portions of the sheet.

9. The method for manufacturing an optical sheet according to claim 1, wherein
in step (b), the liquid material is discharged onto opposing edge portions of the sheet such that the resulting recognition marks will be disposed at a predetermined interval.

10. The method for manufacturing an optical sheet according to claim 1, the method further comprising:
d) cutting the optical sheet based on the recognition marks after step (c).

11. An optical sheet manufactured by the method as recited in claim 1.

12. A method for cutting an optical sheet as recited in claim 11 based on the recognition marks, the method comprising:
a) mounting the optical sheet on a table unit and fixing the optical sheet on the table unit;
b) recognizing the recognition marks formed on the optical sheet at positions corresponding with a desired cutting size by using a recognition unit; and
c) cutting the optical sheet based on the recognized recognition marks by using a cutting machine.

13. The method for cutting an optical sheet according to claim 12, wherein, the table unit has a porous tabletop, and in step (a), the optical sheet is fixed on the table unit by sucking the optical sheet through openings of the porous tabletop.

14. The method for cutting an optical sheet according to claim 12, wherein in step (b), the recognition unit recognizes the recognition marks by obtaining an image of the recognition marks and performing image processing.

15. An optical sheet manufactured by the method as recited in claim 10.

16. An optical sheet comprising.
a sheet having a light-transmitting property;
first micro lenses formed on the sheet; and
second micro lenses formed on the sheet as recognition marks.

17. The optical sheet according to claim 16, wherein
an interval between each of the second micro lenses and any of the first micro lenses is greater than an interval between the first micro lenses.

18. An optical sheet of a desired size obtained by cutting the optical sheet as recited in claim 16 based on the recognition marks.

19. A backlight unit comprising a light source and an optical sheet that diffuses light emitted from the light source, wherein
as the optical sheet, the optical sheet as recited in claim 16 is used.

20. An electro-optic device comprising the backlight unit as recited in claim 19.

21. An electronic device equipped with the electro-optic device as recited in claim 20.
